(19) United States
(12) Patent Application Publication
(10) Pub. No.: US 2023/0230854 A1
(43) Pub. Date: Jul. 20, 2023

(54) POWER MODULE PACKAGING SYSTEMS AND FABRICATION METHODS

(71) Applicants: Wenkai Wu, East Greenwich, RI (US); Kevin Niu, Jiangyin (CN); Cheng Wei Chen, East Greenwich, RI (US)

(72) Inventors: Wenkai Wu, East Greenwich, RI (US); Kevin Niu, Jiangyin (CN); Cheng Wei Chen, East Greenwich, RI (US)

(21) Appl. No.: 17/648,246

(22) Filed: Jan. 18, 2022

(51) Int. Cl. H01L 21/56

(52) U.S. Cl. CPC H01L 21/56

(57) ABSTRACT

A method and system for fabricating a three-dimensional power module packaging structure is provided. The power module packaging method incorporates a one-time SMD-molding process, which simultaneously connects bare semiconductor dies and conductive pillars to the PCB substrate directly.

### BACKGROUND OF THE INVENTION

The present invention relates to power module packaging systems and methods of fabrication, and more particularly, to a method and system for fabricating a three-dimensional (3D) power module packaging structure.

The ever-expanding uses of power electronics systems and their attendant requirements demand significant improvements in their thermal properties and electronic functionality as well as a compact, low three-dimensional profile. Power electronics systems and their constituent power modules include power semiconductor devices and packaging components. The power semiconductor devices include, but are not limited to, transistors, diodes, thermistors, and any electronic circuit component comprising slices made of silicon, germanium, and gallium arsenide, etc., which may be referred to as dies or semiconductor dies. These semiconductor dies may be arranged within the modules to provide electrical functions and topologies. Module packaging aims to provide electrical interconnections, thermal control, and mechanical support to the plurality of semiconductor dies, as well as a reduction in the cost of fabrication.

Currently, some modules packaging includes bare die into which is mounted the package and inductor on a printed circuit board (PCB)/Bismaleimide-Triazine (BT) substrate. Such power module packaging systems involve a lengthy and complex fabrication process. Moreover, the resulting assembly structure embodying such power module packaging systems limits the heat dissipation and electrical performance of the power modules and thus of the overall power electronics system.

Another prior art method of fabricating a 3D power module packaging structure includes embedded die into the BT substrate solution to achieve a low-profile 3D package. However, this approach is not popular for the resulting assembly structures provides low yield, have handling issues during packaging process, and it is hard to detect the embedded die appearance, which facilitates chipping and scratch of the assembly and its constituent semiconductor components. In other words, this prior art solution incurs high cost and difficulties during mass production.

Accordingly, there is a need for a method and system for fabricating a three-dimensional (3D) power module packaging structure embodying a simplified module fabricating process to obtain better heat dissipation and electrical performance. The 3D power module packaging method incorporates a one-time_molding process, which connects bare semiconductor dies (without chip packaging) to the PCB/BT substrate directly, resulting in an overall low-profile, flat footprint even for the associated passive element/inductor component.

### SUMMARY OF THE INVENTION

In one aspect of the present invention, a method for fabricating a semiconductor module packaging structure, the method includes a one-time SMD-molding process simultaneously connecting one or more bare semiconductor dies and one or more conductive pillars to a substrate.

In another aspect of the present invention, the method further includes the following: wherein the one or more conductive pillars are arranged on the substrate to accommodate a passive component of the semiconductor module; forming a mold compound layer encapsulating the one or more bare semiconductor dies and the one or more conductive pillars along the substrate, wherein the mold compound layer is provided through film assist molding; exposing an upper surface of the one or more conductive pillars by removing a portion of the mold compound layer; and seating the passive component on the exposed upper surface of the one or more conductive pillars, wherein the one or more conductive pillars is a plurality of conductive pillars that the seated passive component interconnects, and wherein a periphery of the seated passive component is generally coextensive with a periphery defined by the plurality of conductive pillars.

In yet another aspect of the present invention, the method for fabricating a semiconductor module packaging structure includes a one-time SMD-molding process simultaneously connecting one or more bare semiconductor dies and a plurality of conductive pillars to a substrate, wherein the plurality of conductive pillars are arranged on the substrate to accommodate thereon a copper component of the semiconductor module, the copper component spanning the plurality of conductive pillars.

In yet another aspect of the present invention, the method for fabricating a semiconductor module packaging structure includes a one-time SMD-molding process simultaneously connecting one or more bare semiconductor dies and one or more conductive pillars to a substrate, wherein at least one or the one or more conductive pillars provides an overhang for at least one of the one or more bare semiconductor dies.

These and other features, aspects and advantages of the present invention will become better understood with reference to the following drawings, description and claims.

### BRIEF DESCRIPTION OF THE DRAWINGS

FIG. 1 is a schematic view of the prior art illustrating the semiconductor die 48 and 3*6 package 46 to the BT substrate 44, which makes the electrics path longer than direct mount of the die (in the 3*6 package 46) into the BT substrate 44, and the bottom heat dissipation is limited by this longer path. The 3*6 package 46 also affects topside heat dissipation as mold compound has a lower heat conductivity coefficient. Moreover, the prior art made it more difficult to mount the inductor cores on high inductor feet (denoted by ‘H’) with a machine as the solder paste needed to be sufficiently flay on the BT substrate 44. Finally, the overall topography and height of the inductor metal shield 40 of the prior art was dimensionally problematic in a market demanding ever-shrinking electronic components.

FIG. 2 is a schematic view of an exemplary embodiment of a base of the assembly structure of the present invention.

FIG. 3 is a schematic view of an exemplary embodiment of the base of the assembly structure of the present invention, with mold compound added.

FIG. 4 is a schematic view of an exemplary embodiment of the full assembly structure of the present invention.

FIG. 5 is a schematic view of an exemplary embodiment of the full assembly structure of the present invention, wherein the inductor/passive is not required and where a conductor component 30 is added to increase heat dissipation.

FIG. 6 is a schematic view of an exemplary embodiment of the full assembly structure of the present invention, illustrating the low profile when an inductor/passive is not required, and wherein an alternative conductive pillar 32 is provided, wherein the alternative conductive pillar 32 provides an overhang 33 over the semiconductor die 16 thereby maximizing space usage, keeping the profile lower.

FIG. 7 is a flow chart of an exemplary embodiment of the present invention.

### DETAILED DESCRIPTION OF THE INVENTION

The following detailed description is of the best currently contemplated modes of carrying out exemplary embodiments of the invention. The description is not to be taken in a limiting sense but is made merely for the purpose of illustrating the general principles of the invention, since the scope of the invention is best defined by the appended claims.

Broadly, an embodiment of the present invention provides a method and system for fabricating a three-dimensional power module packaging structure. The power module packaging method incorporates a one-time SMD-molding process, which simultaneously connects bare semiconductor dies and conductive pillars to the PCB substrate directly.

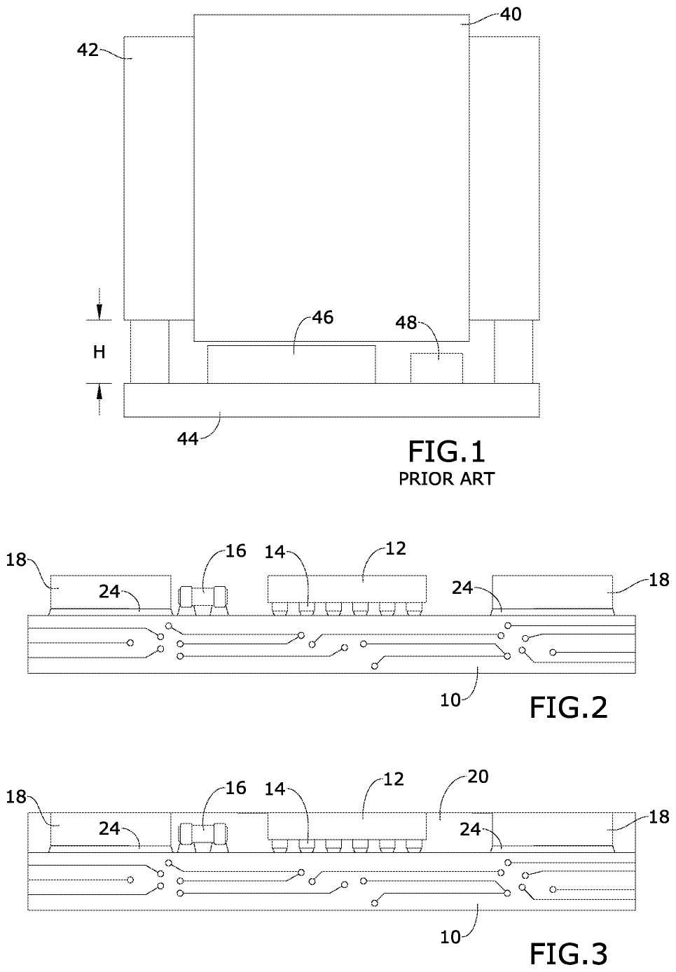

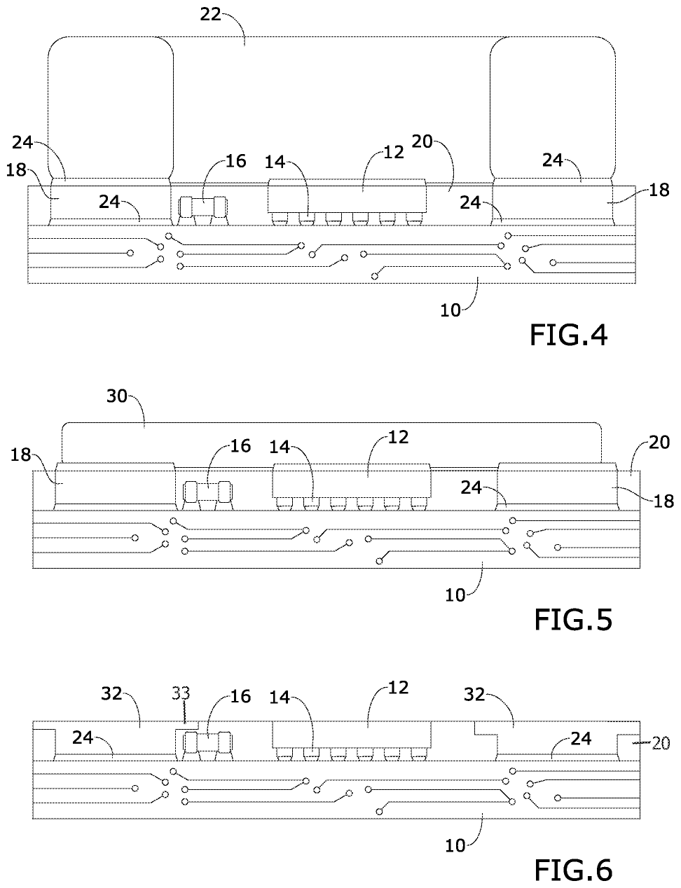

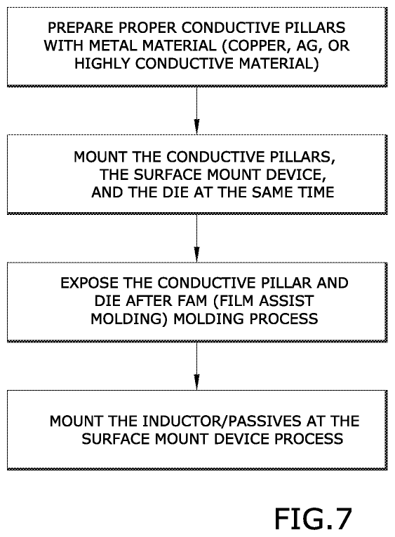

Referring the FIGS. 2 through 7, the disclosure may include a method and system for fabricating a three-dimensional (3D) power module packaging structure which incorporate improvements over the above-mentioned disadvantages of the prior art (FIG. 1).

Surface-mount technology (SMT) is a method in which the electrical components are mounted directly onto the surface of a printed circuit board (PCB). An electrical component mounted in this manner is referred to as a surface-mount device (SMD). SMT allows for increased fabricating automation which reduces cost and improves quality. It also allows for more components to fit on a given area of substrate.

The systemic process disclosed herein may include the following components (and result in an assembly structure comprising said components):

First, a fabricator would make/prepare one or more proper conductive pillars 18 with metallic material, Copper, Ag or other highly conductive material. The dimensions and shape of each conductive pillar may be based on the footprint of an associated inductor/passive component 22 of the resulting power module.

Second, the fabricator may simultaneously “SMD-mount” the following on planar surface of the PCB substrate 10: the conductive pillars 18 and the semiconductor dies 12 and 16 by the way of the solder paste 24, sintering, or other sufficient PCB substrate bonding methodologies. In other words, the fabricator may consider and treat the conductive pillars 18 the same as (and at the same time as) other SMB electrical components/semiconductive dies 12 and 16 that are SMD-mounted directly onto the surface of a printed circuit board. Again, the semiconductor dies 12 and 16 may include power semiconductor devices such as, but not limited to, transistors, diodes, thermistors, and any electronic circuit component comprising slices made of silicon, germanium, and gallium arsenide, etc. Some semiconductor dies 12 may be supported on the PCB by pillars with solder bumps 14 or the like to selectively control the profile and stability of such semiconductor dies 12. Specifically, the solder bumps 14 may be used to have the upper surface/profile of one or more semiconductor dies 12 to align with the upper surface/profile of the conductive pillars 18 (or, alternatively, to ensure that the upper surfaces of the semiconductor dies 12 are selectively offset therefrom).

Third, the fabricator may expose the conductive pillars 18 and the semiconductor dies 12 after adding a mold compound layer 20 by way of a Film Assist Molding (FAM) process. The mold compound layer 20 can be formed using the FAM process including the steps of encapsulating in the mold compound layer 20 (e.g., a silicone gel) through its introduction into open cavities defined by the conductive pillars 18 and semiconductor dies 12 and 16, until an upper surface of the mold compound layer 20 encapsulates all or a portion of the conductive pillars 18 and semiconductor dies 12 and 16. A suitable FAM system allows ultra-thin semiconductor components to be encapsulated on one or more surfaces. Then the fabricator removes the mold film/compound layer 20 to expose the tip portions or upper surfaces of the conductive pillars 18 and possibly the semiconductor dies 12.

Fourth, the fabricator mounts the inductor/passive component(s) 22 at the SMT process on the upper surfaces or tip portions of the conductive pillars 18, whereby the conductive pillars 18 obviate the need for vias utilizing through wires.

Referring to FIG. 5, wherein the inductor/passive component(s) 22 is not required, a conductive component 30 may be interconnect the conductive pillars 18 in lieu of the inductor/passive component 22. The conductive component 30 may be copper of other material that increases heat dissipation.

Referring to FIG. 6, wherein the inductor/passive component(s) 22 is not required, uniquely shaped conductive pillars 22 may be provided to maintain the lowest possible profile. Including, in certain embodiments, wherein the uniquely shaped conductive pillars 22 have an overhang 33 upward of the semiconductor die 16. Additionally, the overhangs enable a bigger surface area of conductive pillars at the FAM surface side to have better heat dissipation efficiency.

Though the 3D power module packaging structure of the disclosure has a SMD package structure, the power module packaging structure need not limited be to the SMD package structure. The 3D power module packaging structure embodied in the disclosure can be easily fabricated through the fabricating processes described above. Thus, the 3D power module packaging structure can be made compact while providing high quality operation characteristics. Accordingly, the overall profile of the 3D power module packaging structure can be desirably reduced as compared to the case when wire bonding is used. Finally, thermal conductivity mismatch can be minimized as a function of the compacted profile of the 3D power module packaging structure and a selection of a substrate formed of an appropriate material.

As used in this application, the term “about” or “approximately” refers to a range of values within plus or minus 10% of the specified number. And the term “substantially” refers to a similar 10% difference relative to an associated entirety. The use of any and all examples, or exemplary language (“e.g.,” “such as,” or the like) provided herein, is intended merely to better illuminate the embodiments and does not pose a limitation on the scope of the embodiments or the claims. No language in the specification should be construed as indicating any unclaimed element as essential to the practice of the disclosed embodiments.

In the following description, it is understood that terms such as “first,” “second,” “top,” “bottom,” “up,” “down,” and the like, are words of convenience and are not to be construed as limiting terms unless specifically stated to the contrary.

It should be understood, of course, that the foregoing relates to exemplary embodiments of the invention and that modifications may be made without departing from the spirit and scope of the invention as set forth in the following claims.

What is claimed is:

1. A method for fabricating a semiconductor module packaging structure, the method comprising: a one-time SMD-molding process simultaneously connecting one or more bare semiconductor dies and one or more conductive pillars to a substrate.

2. The method of claim 1, wherein the one or more conductive pillars are arranged on the substrate to accommodate a passive component of the semiconductor module.

3. The method of claim 1, further comprising forming a mold compound layer encapsulating the one or more bare semiconductor dies and the one or more conductive pillars along the substrate.

4. The method of claim 3, wherein the mold compound layer is provided through film assist molding.

5. The method of claim 3, exposing an upper surface of the one or more conductive pillars by removing a portion of the mold compound layer.

6. The method of claim 3, seating the passive component on the exposed upper surface of the one or more conductive pillars.

7. The method of claim 6, wherein the one or more conductive pillars is a plurality of conductive pillars that the seated passive component interconnects.

8. The method of claim 7, wherein a periphery of the seated passive component is generally coextensive with a periphery defined by the plurality of conductive pillars.

9. A method for fabricating a semiconductor module packaging structure, the method comprising: a one-time SMD-molding process simultaneously connecting one or more bare semiconductor dies and a plurality of conductive pillars to a substrate, wherein the plurality of conductive pillars are arranged on the substrate to accommodate thereon a copper component of the semiconductor module, the copper component spanning the plurality of conductive pillars.

10. A method for fabricating a semiconductor module packaging structure, the method comprising: a one-time SMD-molding process simultaneously connecting one or more bare semiconductor dies and one or more conductive pillars to a substrate, wherein at least one or the one or more conductive pillars provides an overhang for at least one of the one or more bare semiconductor dies.
